(19) United States
(12) Patent Application Publication
(10) Pub. No.: US 2018/0261704 A1
(43) Pub. Date: Sep. 13, 2018

(54) MONOLITHIC INTEGRATION OF DISSIMILAR PHOTOVOLTAIC LAYERS IN WEARABLE DEVICES

(71) Applicant: Intel Corporation, Santa Clara, CA (US)

(72) Inventors: John F. Jacobs, San Jose, CA (US); Kunjal Parikh, San Jose, CA (US); Naoki Matsumura, San Jose, CA (US); David Rosales, Berkeley, CA (US)

(21) Appl. No.: 15/457,817

(22) Filed: Mar. 13, 2017

(51) Int. Cl. H01L 31/0352; H01L 31/0725; H01L 31/0216; H01L 31/18; H01L 31/0328

(52) U.S. Cl. CPC H01L 31/0352; H01L 31/0725; H01L 31/0328; H01L 31/18; H01L 31/0216

(57) ABSTRACT

An apparatus is provided which comprises: a surface; a first photovoltaic layer formed on a first section of the surface; and a second photovoltaic layer formed on a second section of the surface, wherein a transparency of the first photovoltaic layer is different from a transparency of the second photovoltaic layer.

### BACKGROUND

Computing devices (e.g., consumer electronic devices, wearable devices, Internet-of-things (IOT), etc.) may often be powered by rechargeable batteries. A battery in a computing device may be recharged and/or the computing device may be powered using, for example, power generated from photovoltaic cells.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 schematically illustrates a device comprising a surface on which dissimilar photovoltaic layers are to be formed, according to some embodiments.

FIG. 2 schematically illustrates two dissimilar photovoltaic layers disposed on a surface of the device of FIG. 1, according to some embodiments.

FIG. 3 schematically illustrates a plurality of dissimilar photovoltaic layers disposed on the surface of the device of FIG. 1, according to some embodiments.

FIGS. 4A-4C illustrate various operations associated with monolithic integration of dissimilar photovoltaic layers on the surface of the device of FIG. 1, according to some embodiments.

FIG. 5 illustrates a flowchart depicting a method for forming dissimilar photovoltaic layers having varying degree of transparencies on a surface of a device, according to some embodiments.

FIG. 6 illustrates a computer system or a SoC (System-on-Chip), where dissimilar photovoltaic layers having varying degree of transparencies are used for generating power, in accordance with some embodiments.

### DETAILED DESCRIPTION

In some embodiments, a transparency of photovoltaic layers (e.g., which may comprise photovoltaic cells) may be measured using transmittance or another appropriate measurement unit. In some examples, generally, the more transparent the photovoltaic cells, the less efficient are the photovoltaic cells. For example, a relatively more transparent photovoltaic layer (e.g., a relatively less opaque photovoltaic layer having relatively higher transmittance) is able to capture less energy than a relatively less transparent photovoltaic layer (e.g., a relatively more opaque photovoltaic layer having relatively lower transmittance).

In some embodiments, a device (e.g., a wearable device, a IOT, a consumer electronic device, or the like) may have photovoltaic layers disposed thereon, e.g., for generating electrical power from ambient light. Areas on the device, where such photovoltaic layers can be disposed, may be limited. Accordingly, some sections of the device (e.g., where there are no display elements) may have opaque or near opaque photovoltaic layers disposed thereon, while some other sections of the device (e.g., where there are display elements, such as the screen) may have transparent or near transparent photovoltaic layers disposed thereon. In some embodiments, the dissimilar photovoltaic layers may be monolithically formed on the device.

There are many technical effects of the various embodiments. For example, in various embodiments, dissimilar photovoltaic layers (e.g., having dissimilar levels of transparencies) may be formed on computing devices. Opaque or near opaque photovoltaic layers may have relatively higher light absorption capacity and may generate higher power (e.g., per square millimeter), e.g., compared to transparent or near transparent photovoltaic layers. The combination of the opaque or near opaque photovoltaic layers and the transparent or near transparent photovoltaic layers may produce relatively higher power (e.g., compared to situations where only opaque or near opaque photovoltaic layers are used, or situations where only transparent or near transparent photovoltaic layers are used). In some embodiments, the power produced by the photovoltaic layers may be used to recharge a battery of the device, maintain perpetual time using a rechargeable battery (e.g., so that once the time is set in the watch, the time is maintained even during the battery replacement procedure), and/or the like. Other technical effects will be evident from the various embodiments and figures.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.” The terms “substantially,” “close,” “approximately,” “near,” and “about,” generally refer to being within +/−10% of a target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

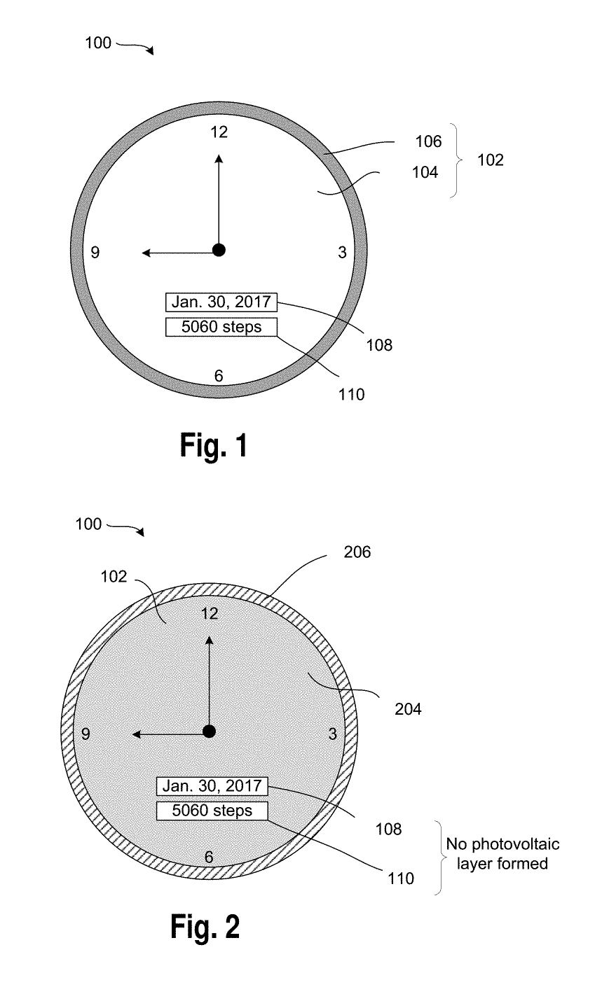

FIG. 1 schematically illustrates a device 100 comprising a surface 102 on which dissimilar photovoltaic layers are to be formed, according to some embodiments. In the example of FIG. 1, the device 100 is a watch (e.g., to be worn on a wrist of a user), and accordingly, the device 100 may also be interchangeably referred to as a “watch 100” herein. The device 100 has the surface 102. The surface 102, for example, may be exposed to ambient light when the device 100 is used by a user. For example, in the example of FIG. 1 in which the device 100 is a watch, the surface 102 may represent a front face or a front surface of the watch. Although FIG. 1 illustrates the surface 102 of the device 100 being circular in shape, the surface 102 of the device 100 can have any other appropriate shape, e.g., square, rectangular, oval, elliptical, or the like.

In some embodiments, the surface 102 may comprise a display surface 104. The display surface 104, for example, may comprise the surface of the device 100 on which information is displayed. For example, the display surface 104 may comprise the surface on which the dials (e.g., comprising the numbers representing the hours and minutes, such as 3, 6, 9, and 12), the minute and hour hands (and possibly a second hand), and/or other information may be displayed.

In some embodiments, the display surface 104 may comprise a date area 108 where, for example, a current date may be displayed in an appropriate format.

In some embodiments, the device 100 may also act as a fitness tracker, in which case the display surface 104 may display information such as a number of steps taken in a day by a user, a heart rate of the user, an activity pattern of the user, and/or the like, as would be readily understood by those skilled in the art. In such an example, the display surface 104 may comprise an activity information area 110 to display such information.

Although the surface 102 of the watch 100 in FIG. 1 (and also in some subsequent figures) is illustrated to have specific components (e.g., a minute hand, an hour hand, date area 108, activity information area 110, etc.), other variations of the watch 100 may be easily envisioned by those skilled in the art based on the teachings of this disclosure. Merely as an example, the watch 100 may not have any hands, and may display time digitally (e.g., by digitally displaying numbers to indicate time). In another example, a second hand may be present in addition to the hour and minute hands. In yet other examples, hands to display a stop watch and/or an alarm may be present. In another example, no date area may be present in the watch 100. Such variations of the watch 100 would be readily understood and appreciated by those skilled in the art based on the teachings of this disclosure.

In some embodiments, the display surface 102 may be a transmissive display surface, a transreflective display surface, an emissive display surface, a reflective display surface, and/or the like. In some embodiments, Liquid Crystal Display (LCD), Light Emitting Diode (LED), organic LED, and/or another appropriate display technique may be used to display various display elements on the display surface 104. Although some example display elements on the display surface 104 are illustrated in FIG. 1, the display surface 104 may include any other appropriate display elements, e.g., a dial representing seconds, a second hand, other numbers or indicators representing hours, minutes, seconds, identification of a manufacturer and/or a make of the watch 100, a menu for configuring the device 100, etc.

In some embodiments, as illustrated in FIG. 1, the watch 100 may have two hands for minutes and hours (or have more hands, e.g., to indicate seconds). In some embodiments, the hands displayed on the display surface 104 may comprise two mechanical or physical hands that move with time (e.g., if the hands are analog in nature). In some other embodiments, the hands may be digitally displayed on the display surface 104.

In some embodiments, in addition to the display surface 104, the surface 102 may also include a bezel surface 106. In some embodiments, the bezel surface 106 may be located along the periphery of the watch. The bezel surface 106 may have a bezel of the watch (not illustrated in FIG. 1) formed thereon.

Because the bezel surface 106 may have the bezel of the watch, no information may be displayed on the bezel surface 106. In some embodiments, the bezel surface 106 may also be referred to as a non-display section or a non-display area. It may be noted that sections of the display surface 104, which may not be configured to display anything, may also be referred to as a non-display area.

Although not illustrated in FIG. 1, in some embodiments, power to operate the device 100 may be received from a battery included in the device 100. In some embodiments, the battery may be recharged using power from an external source (e.g., power received via a Universal Serial Bus (USB) link, power received via an Alternating Current (AC) power adapter, etc.). In some embodiments, the battery may also be recharged using power generated by photovoltaic layers disposed on the surface 102, as discussed herein in more detail.

In general, photovoltaics is a method for generating electric power by using photovoltaic cells or solar cells to convert energy from the sun or another appropriate artificial source of light (e.g., from ambient light) into a flow of electrons. The photovoltaic effect refers to photons of light exciting electrons into a higher state of energy, allowing them to act as charge carriers for an electric current. Thus, a photovoltaic cell converts the energy of light directly into electricity by the photovoltaic effect, which is a physical and chemical phenomenon.

In some embodiments, photovoltaic cells may be layered on the surface 102 (e.g., under a cover lens of the watch 100). Such photovoltaic layers on the surface 102 may provide an opportunity to capture ambient light and convert to energy. Such energy may be used to power the device 100 and/or to recharge a battery of the device 100, e.g., thereby extending the time that the device 100 may operate without needing a recharge.

In an example, a transparency of photovoltaic layers may be measured using transmittance or another appropriate measurement unit. In some examples, generally, the more transparent the photovoltaic cells are, the less efficient are the photovoltaic cells. For example, a relatively more transparent photovoltaic layer (e.g., a relatively less opaque photovoltaic layer having relatively higher transmittance) may be able to capture less energy than a relatively less transparent photovoltaic layer (e.g., a relatively more opaque photovoltaic layer having relatively lower transmittance).

As discussed, the display surface 104 may have information displayed thereon (e.g., information such as the two hands, date, activity information, numbers representing the minutes, and/or other information not illustrated in FIG. 1). Thus, if relatively less transparent (e.g., more opaque) photovoltaic layers are formed on the display surface 104, then such less transparent photovoltaic layers may render such information less visible or unclear to the user. On the other hand, no meaningful information may be displayed on the bezel surface 106, and hence, the bezel surface 106 may be covered with relatively less transparent (e.g., more opaque) photovoltaic layers.

FIG. 2 schematically illustrates two dissimilar photovoltaic layers (e.g., having dissimilar levels of transparencies) disposed on the surface 102 of the device 100 of FIG. 1, according to some embodiments. In some embodiments, first photovoltaic layer 204 (e.g., illustrated using grey shading) comprising a first type of photovoltaic material may be formed on sections of the display surface 104. In some embodiments, second photovoltaic layer 206 (e.g., illustrated using diagonal lines) comprising a second type of photovoltaic material may be formed on the bezel surface 106. Although FIG. 2 illustrates the photovoltaic layers 204 and 206 using specific shadings, these shadings are merely for illustration, and does not indicate the texture or color of these photovoltaic layers.

In some embodiments, meaningful information may be displayed on the display surface 104, or at least in some sections of the display surface 104. Also, in an example, no meaningful information may be displayed on the bezel surface 106. Accordingly, the photovoltaic layer 204 formed on sections of the display surface 104 may be relatively more transparent (e.g., to enable the user to view the sections of the display surface through the photovoltaic layer 204). On the other hand, the photovoltaic layer 206 formed on the bezel surface 106 may be relatively less transparent, e.g., may be opaque or near opaque (e.g., because nothing may be displayed beneath the photovoltaic layer 206).

Thus, the opaque or near opaque photovoltaic layer 206 formed on the bezel surface 106 may produce relatively higher electrical power than, for example, the relatively transparent photovoltaic layer 204 formed on sections of the display surface 104. The combination of the power produced from the photovoltaic layers 204 and 206 may be sufficient or near sufficient to recharge the battery (e.g., compared to a situation when only the opaque or near opaque photovoltaic layer 206 is used).

In some embodiments, at least some sections of the display surface 104 may not have any photovoltaic layers formed thereon. For example, in the example of FIG. 2, the date area 108 and the activity information area 110 may not have any photovoltaic layers formed thereon, e.g., to enable the user to clearly view the information displayed in these areas.

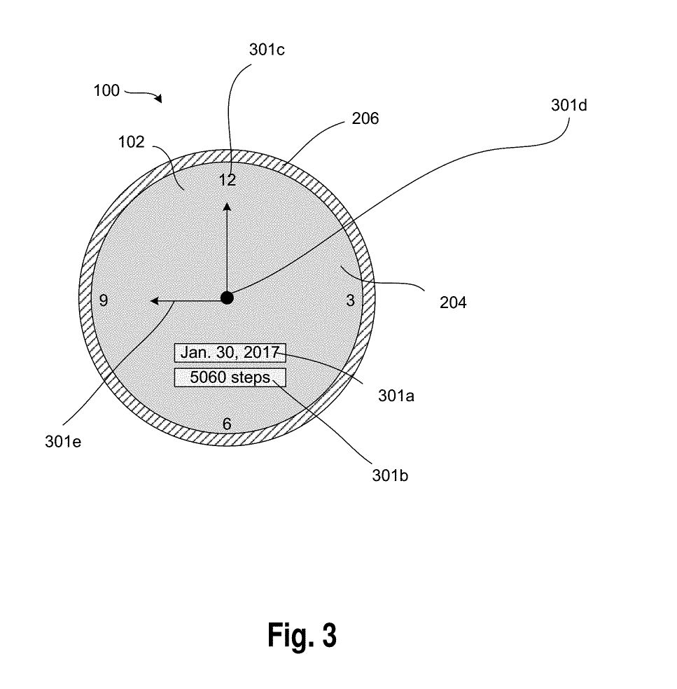

FIG. 2 illustrates two dissimilar photovoltaic layers 204 and 206 disposed on the surface 102 of the device 100. However, in some embodiments, more than two dissimilar photovoltaic layers may be formed on the surface 102. For example, FIG. 3 schematically illustrates a plurality of dissimilar photovoltaic layers (e.g., having dissimilar levels of transparencies) disposed on the surface 102 of the device 100 of FIG. 1, according to some embodiments. For example, in FIG. 3, photovoltaic layers 204 and 206 may be formed on sections of the display surface 104 and the bezel surface 106, respectively, e.g., as discussed with respect to FIG. 2.

Additionally, in some embodiments, photovoltaic layer 301a may be formed on the date area 108 and/or photovoltaic layer 301b may be formed on the activity information area 110. In some embodiments, because the date area 108 and the activity information area 110 display meaningful information, the photovoltaic layers 301a and/or 301b may be even more transparent than the photovoltaic layer 204. For example, the photovoltaic layers 301a and/or 301b may be almost transparent such that the date and/or the activity information may be clearly visible through the photovoltaic layers 301a and/or 301b. Because the power generated by less transparent photovoltaic layers are relatively less, the power generated by the photovoltaic layers 301a and/or 301b (e.g., per square millimeter) may be even less than the power generated by the photovoltaic layer 204 (e.g., per square millimeter), but even the small amount of power generated by the photovoltaic layers 301a and/or 301b may still contribute to the total power generated by photovoltaic layers formed on the surface 102.

In an example, in FIG. 3, photovoltaic layers 301c may be formed on various numbers and characters that may be permanently or near permanently displayed or embedded on the display surface 104. For example, the numbers 3, 6, 9, and 12 (or any other number on the dial of the watch 100) used to indicate the time may have photovoltaic layers 301c formed thereon. In some embodiments, these numbers may be mechanical or physical shapes embedded on the display surface 104. Accordingly, the photovoltaic layers 301c may be opaque or near opaque (e.g., relatively less transparent compared to the photovoltaic layer 206). Although not illustrated in FIG. 3, in some embodiments, such photovoltaic layers 301c may be used to form letters, numbers, logos, and/or characters to indicate a make and/or model of the watch 100, or other information on the watch 100.

In an example, in FIG. 3, photovoltaic layer 301d may be formed on a center point of the display surface 104 (e.g., where the minute and hour hands intersect). No meaningful information may be displayed on this center point, and hence, in some embodiments, the photovoltaic layer 301d may be relatively more opaque.

In an example, in FIG. 3, photovoltaic layers 301e may be formed on the hour and minute hands, and the second hand as well, e.g., if such a second hand is present (e.g., assuming that the watch 100 is analog, and the hands of the watch 100 are mechanical hands that physically move). In some embodiments, the photovoltaic layer 301e may be relatively more opaque and may be displayed as being part of the minute and hour hands.

Although FIGS. 2-3 illustrate various examples of dissimilar photovoltaic layers disposed on the surface 102 of the device 100, various other example dissimilar photovoltaic layers may be envisioned by those skilled in the art, e.g., based on the teachings of this disclosure. For example, if the watch 100 is an analog watch, relatively more opaque photovoltaic layers may be formed on the dials.

In another example, a center of the display surface 104 may have more meaningful information compared to edges of the display surface 104. Accordingly, in some embodiments, a transparency of the photovoltaic layer 204 may continually or gradually become less when traversing from a center of the display surface 104 towards the edge of the display surface 104. For example, if multiple concentric circles are imagined centering the center of the display surface 104, the transparency of the photovoltaic layer 204 on the inner circles may be more than the transparency of the photovoltaic layer 204 on the outer circles.

In yet another example, the photovoltaic layers may be patterned (e.g., formed in specific patterns) and used as an aesthetic tool to create designs on the surface 102. For example, alternate layers of opaque and transparent photovoltaic materials may be used to create designs on the surface 102.

Although FIGS. 1-2 illustrate forming dissimilar photovoltaic layers on the surface 102, in some embodiments, in addition to or instead of forming photovoltaic layers on the surface 102, one or more photovoltaic layers may also be formed on a cover glass (not illustrated in the figures) covering the surface 102. For example, one or more photovoltaic layers may be formed on a top surface and/or a bottom surface of the cover glass covering the surface 102.

In some embodiments, in FIGS. 1-3, a width of the bezel surface 106 may be based on a variety of factors, e.g., a design, make and model of the watch 100, preference of the manufacturer, and also on a desired area covered by the opaque or near opaque photovoltaic layer 206 (e.g., which may translate to a desired amount of power generated from the photovoltaic layer 206).

In some embodiments, a transmittance of a photovoltaic layer (e.g., which may control whether the photovoltaic layer is more or less transparent) in the watch 100 may be controlled by a variety of techniques. For example, referring to FIG. 2, different types of photovoltaic materials may be used for the photovoltaic layers 206 and 204. For example, relatively more transparent photovoltaic material may be used for the photovoltaic layer 204, and relatively less transparent photovoltaic material may be used for the photovoltaic layer 206. In another example, relatively lower density photovoltaic material may be used for the photovoltaic layer 204, and relatively higher density photovoltaic material may be used for the photovoltaic layer 206, thereby leading to the difference in transparencies. Thus, in this example, by controlling the type of material used, the transparency of the photovoltaic layers may be controlled.

In another example, the photovoltaic layer 204 may have a smaller number of layers of photovoltaic material (e.g., a single layer of photovoltaic material), thereby leading to relatively more transparency. On the other hand, the photovoltaic layer 206 may have higher number of layers of photovoltaic material, thereby leading to relatively less transparency of the photovoltaic layer 206. Thus, in this example, by controlling a number of layers of the photovoltaic material, the transparency of the photovoltaic layers may be controlled.

In yet another example, the photovoltaic layer 204 may be relatively thinner, thereby leading to relatively more transparency of the photovoltaic layer 204. On the other hand, the photovoltaic layer 206 may be relatively thicker, thereby leading to relatively less transparency of the photovoltaic layer 206. Thus, in this example, by controlling a thickness of the photovoltaic material, the transparency of the photovoltaic layers may be controlled.

Thus, in some embodiments, transparency of a photovoltaic layer may be controlled by one or more of controlling a type of photovoltaic material used, controlling a number of layers of the photovoltaic material and/or controlling a thickness of the photovoltaic layer.

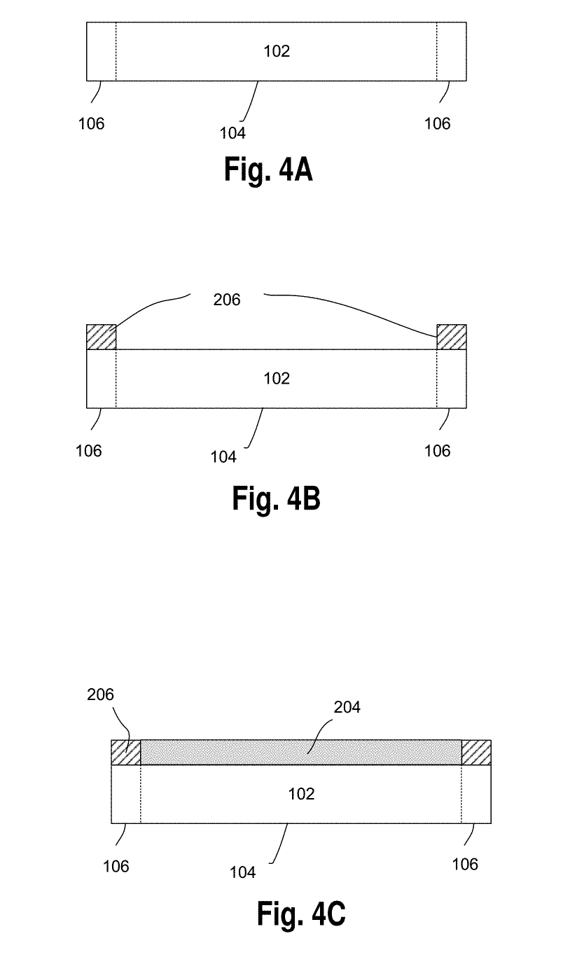

FIGS. 4A-4C illustrate various operations associated with monolithic integration of dissimilar photovoltaic layers on the surface 102 of the device 100, according to some embodiments. FIGS. 4A-4C illustrate cross-sectional views of the device 100. Not all elements are illustrated in the cross-sectional view of these figures—rather, only the top surface 102 of the device 100 and various photovoltaic layers formed of the surface 102 are illustrated in these figures.

Referring to FIG. 4A, illustrated is the surface 102 of the device 100 of FIG. 1. The surface 102 comprises the bezel surface 106 disposed on the edges (e.g., along the circumference of the surface 102, as illustrated in FIG. 1) and the display surface 104. Two dotted lines in FIG. 4A separate the bezel surface 106 from the display surface 104, although the device 100 may not have any such separation lines. In some embodiments, the surface 102 of FIG. 4A may comprises glass, film, or another appropriate material. In some embodiments, beneath the surface 102 (e.g., beneath the display surface 104) there may be display mechanism such as an LCD screen, an LED screen, and/or another type of display screen, although such display mechanism is not illustrated in FIGS. 4A-4C.

Referring now to FIG. 4B, photovoltaic layer 206 may be formed on the bezel surface 106. The photovoltaic layer 206 may be formed on the bezel surface 106 by any appropriate manner. Merely as an example, a mask layer (not illustrated in the figures) may be overlaid on the display surface 104 of FIG. 4A (e.g., such that the mask layer may not cover the bezel surface 106), and then photovoltaic material may be deposited on the exposed bezel surface 106 using an appropriate technique (e.g., using evaporation tool or another appropriate manner), thereby forming the photovoltaic layer 206 on the bezel surface 106. The mask layer may then be removed.

In some embodiments and although not illustrated in the figures, the photovoltaic layer 206 may comprises one or more layers of photovoltaic material. For example, each such layer of photovoltaic material may also have a bottom electrode layer disposed on the bottom of the photovoltaic material layer and a top electrode layer disposed on the top of the photovoltaic material layer. Such layers of top electrodes, bottom electrodes and photovoltaic materials may be deposited, for example, by covering the display surface 104 using the mask layer and stacking the various layers, e.g., as discussed above.

As discussed herein, the photovoltaic layer 206 may be made relatively less transparent (e.g., opaque, near opaque, or relatively more opaque) by one or more of a number of ways. For example, the photovoltaic material for forming the photovoltaic layer 206 may be relatively less transparent and/or more dense, the photovoltaic layer 206 may be relatively thick, and/or more than one layer of photovoltaic material may be deposited to form the photovoltaic layer 206.

Referring now to FIG. 4C, photovoltaic layer 204 may be formed on the display surface 104. The photovoltaic layer 204 may be formed on the display surface 104 by any appropriate manner. Merely as an example, another mask layer (not illustrated in the figures) may be overlaid on the photovoltaic layer 206 of FIG. 4B (e.g., such that the mask layer may not cover the display surface 104), and then photovoltaic material may be deposited on the exposed display surface 104 using an appropriate technique (e.g., using evaporation tool or another appropriate manner), thereby forming the photovoltaic layer 204 on the display surface 104. In an example where the data area 108 and/or the activity information area 110 are not to be covered with the photovoltaic layer 204 (e.g., as discussed with respect to FIG. 2), the data area 108 and/or the activity information area 110 may also be covered with the mask layer to prevent the formation of the photovoltaic layer 204 thereon. The mask layer may then be removed.

As discussed previously herein, the photovoltaic layer 206 may be made relatively more transparent by one or more of a number of ways. For example, the photovoltaic material for forming the photovoltaic layer 206 may be relatively more transparent and/or less dense, the photovoltaic layer 206 may be relatively thin compared to the photovoltaic layer 206 (although FIG. 4C illustrates the photovoltaic layers 204 and 206 having about similar thickness), and/or relatively less number of layers (e., a single layer) of photovoltaic material may be deposited to form the photovoltaic layer 204.

In some embodiments where additional photovoltaic layers 301a, 301b, 301c, 301d and/or 301e may also be formed (e.g., as discussed with respect to FIG. 3), the sections of the display surface 104 may be masked while depositing the photovoltaic layer 204. Subsequently, the photovoltaic layers 204 and 206 may be masked, and photovoltaic layers 301a, 301b, 301c, 301d and/or 301e may be formed on the respective areas, as would be readily understood by those skilled in the art based on the teachings of this disclosure.

Although not illustrated in FIGS. 4A-4C, electrodes associated with various photovoltaic layers may also be formed using any appropriate technique for forming such electrodes. In some embodiments, top electrodes (e.g., electrodes disposed above the surface 102) may be transparent such that the top electrodes are not visible to a user of the device 100. In some embodiments, the top electrodes may be mounted on a section of the device 100 (e.g., near an edge of the surface 102) such that the top electrodes are not visible to the user.

FIGS. 1-4C discuss forming dissimilar photovoltaic layers on a surface of the watch 100. However, the teachings of this disclosure may be applied to any other appropriate devices as well, such as wearable devices, consumer electronic devices, handheld computing devices, IOTs, or any other appropriate computing devices, e.g., smart glasses, fitness trackers, activity monitors, cellular phones, navigation devices, wearable medical devices, augmented reality devices, virtual reality devices, mixed reality devices, and/or the like. For example, dissimilar photovoltaic layers (e.g., having varying degree of transparencies) may be formed on any of these devices using monolithic integration of these layers.

Merely as an example, dissimilar photovoltaic layers may be formed on smart glasses. Smart glasses are wearable computer glasses that add information alongside or to what the wearer sees. This may be achieved through an optical head-mounted display (OHMD) or embedded wireless glasses with transparent heads-up display (HUD) or augmented reality (AR) overlay that has the capability of reflecting projected digital images as well as allowing the user to see through it, or see better with it. In some embodiments, opaque or near opaque photovoltaic layers may be formed on a rim and/or a frame of smart glasses, and transparent or near transparent photovoltaic layers may be formed on sections of the lens or display area of the smart glasses.

In another example, dissimilar photovoltaic layers may be formed on handheld devices like cellular phones. In some embodiments, opaque or near opaque photovoltaic layers may be formed on the sides and back of the cellular phone (e.g., sections of the cellular phone that does not have any display), and transparent or near transparent photovoltaic layers may be formed on the display (or at least sections of the display).

There are many technical effects of the various embodiments. For example, in various embodiments, dissimilar photovoltaic layers (e.g., having dissimilar levels of transparencies) may be formed on computing devices such as the device 100. For example, sections of the device 100 that does not have any display may have opaque or near opaque photovoltaic layers (e.g., photovoltaic layer 206) formed thereon. Also, sections of the device 100 having a display surface may have transparent or near transparent photovoltaic layers (e.g., photovoltaic layer 204) formed thereon. The opaque or near opaque photovoltaic layers may have relatively higher light absorption capacity and may generate higher power (e.g., per square millimeter), e.g., compared to the transparent or near transparent photovoltaic layers. The combination of the opaque or near opaque photovoltaic layers and the transparent or near transparent photovoltaic layers may produce relatively higher power (e.g., compared to situations where only opaque or near opaque photovoltaic layers are used, or situations where only transparent or near transparent photovoltaic layers are used). In some embodiments, the power produced by the photovoltaic layers may be used to recharge a battery, maintain perpetual time using a rechargeable battery, which may or may not be different from a main battery of the watch (e.g., so that once the time is set in the watch, the time is maintained even during the battery replacement procedure), and/or the like.

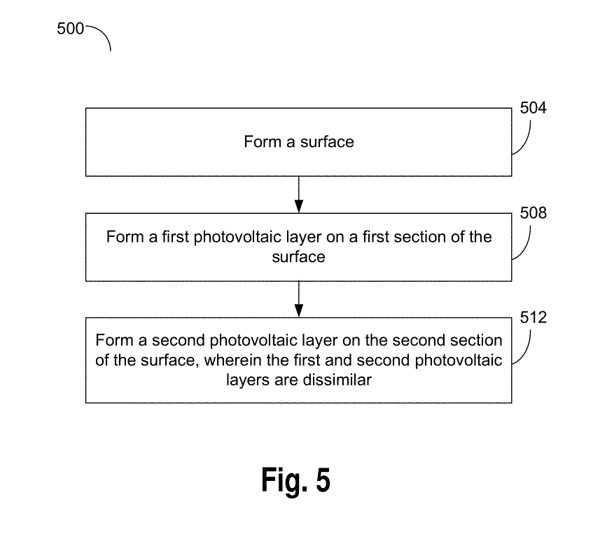

FIG. 5 illustrates a flowchart depicting a method 500 for forming dissimilar photovoltaic layers having varying degree of transparencies on a surface (e.g., surface 102) of a device (e.g., the device 100 of FIGS. 1-4C), according to some embodiments.

Although the blocks in the flowchart with reference to FIG. 5 are shown in a particular order, the order of the actions can be modified. Thus, the illustrated embodiments can be performed in a different order, and some actions/blocks may be performed in parallel. Some of the blocks and/or operations listed in FIG. 5 are optional in accordance with certain embodiments. The numbering of the blocks presented is for the sake of clarity and is not intended to prescribe an order of operations in which the various blocks must occur. Additionally, operations from the various flows may be utilized in a variety of combinations.

At 504, the surface is formed, e.g., as discussed with respect to FIG. 4A. At 508, a first photovoltaic layer (e.g., photovoltaic layer 206) may be formed on a first section of the surface (e.g., the bezel surface 106), e.g., as discussed with respect to FIG. 4B. At 512, a second photovoltaic layer (e.g., photovoltaic layer 204) may be formed on a second section of the surface (e.g., on sections of the display surface 104), e.g., as discussed with respect to FIG. 4C. In some embodiments, the first and second photovoltaic layers may be dissimilar, e.g., may have different degrees of transparencies. In some embodiments, the first and second photovoltaic layers may be monolithically integrated.

Although the blocks in the flowchart with reference to FIG. 5 are shown in a particular order, the order of the actions can be modified. Thus, the illustrated embodiments can be performed in a different order, and some actions/blocks may be performed in parallel. Some of the blocks and/or operations listed in FIG. 5 are optional in accordance with certain embodiments. The numbering of the blocks presented is for the sake of clarity and is not intended to prescribe an order of operations in which the various blocks must occur.

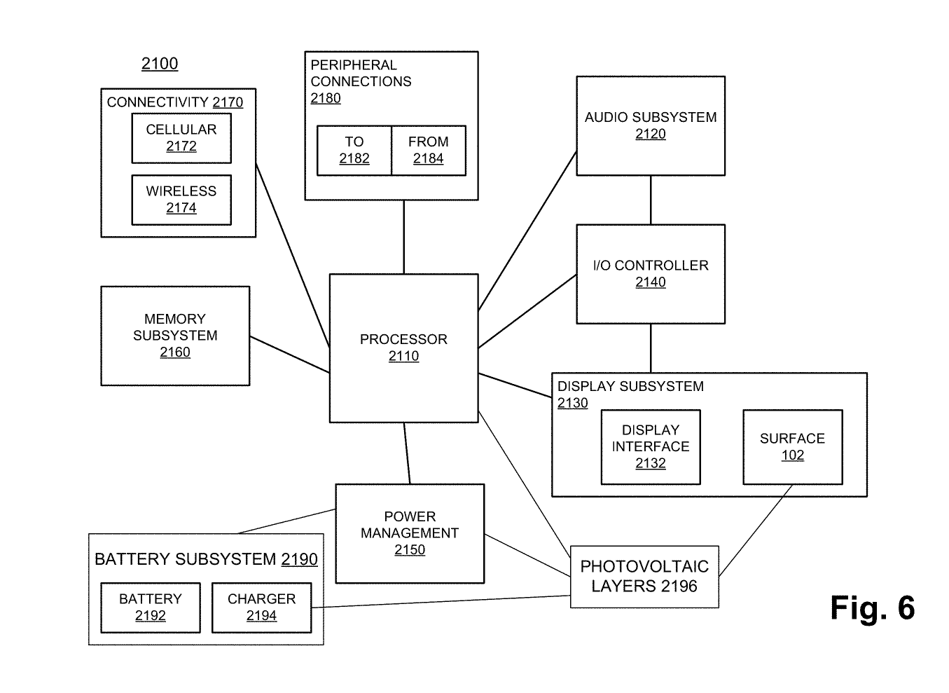

FIG. 6 illustrates a computer system or a SoC (System-on-Chip) 2100, where dissimilar photovoltaic layers having varying degree of transparencies are used for generating power, in accordance with some embodiments. It is pointed out that those elements of FIG. 6 having the same reference numbers (or names) as the elements of any other figure can operate or function in any manner similar to that described, but are not limited to such.

In some embodiments, computing device 2100 represents an appropriate computing device, such as a computing tablet, a mobile phone or smart-phone, a laptop, a desktop, an IOT device, a server, a set-top box, a wireless-enabled e-reader, or the like. It will be understood that certain components are shown generally, and not all components of such a device are shown in computing device 2100.

In some embodiments, computing device 2100 includes a first processor 2110. The various embodiments of the present disclosure may also comprise a network interface within 2170 such as a wireless interface so that a system embodiment may be incorporated into a wireless device, for example, cell phone or personal digital assistant.

In one embodiment, processor 2110 can include one or more physical devices, such as microprocessors, application processors, microcontrollers, programmable logic devices, or other processing means. The processing operations performed by processor 2110 include the execution of an operating platform or operating system on which applications and/or device functions are executed. The processing operations include operations related to I/O (input/output) with a human user or with other devices, operations related to power management, and/or operations related to connecting the computing device 2100 to another device. The processing operations may also include operations related to audio I/O and/or display I/O.

In one embodiment, computing device 2100 includes audio subsystem 2120, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 2100, or connected to the computing device 2100. In one embodiment, a user interacts with the computing device 2100 by providing audio commands that are received and processed by processor 2110.

Display subsystem 2130 represents hardware (e.g., display devices) and software (e.g., drivers) components that provide a visual and/or tactile display for a user to interact with the computing device 2100. Display subsystem 2130 includes display interface 2132, which includes the particular screen or hardware device used to provide a display to a user. In one embodiment, display interface 2132 includes logic separate from processor 2110 to perform at least some processing related to the display. In one embodiment, display subsystem 2130 includes a touch screen (or touch pad) device that provides both output and input to a user.

In some embodiments, the display subsystem 2130 comprises the surface 102. In some embodiments, dissimilar photovoltaic layers 2196 (e.g., similar to the photovoltaic layers discusses with respect to FIGS. 1-4C) may be formed on the surface 102.

I/O controller 2140 represents hardware devices and software components related to interaction with a user. I/O controller 2140 is operable to manage hardware that is part of audio subsystem 2120 and/or display subsystem 2130. Additionally, I/O controller 2140 illustrates a connection point for additional devices that connect to computing device 2100 through which a user might interact with the system. For example, devices that can be attached to the computing device 2100 might include microphone devices, speaker or stereo systems, video systems or other display devices, keyboard or keypad devices, or other I/O devices for use with specific applications such as card readers or other devices.

As mentioned above, I/O controller 2140 can interact with audio subsystem 2120 and/or display subsystem 2130. For example, input through a microphone or other audio device can provide input or commands for one or more applications or functions of the computing device 2100. Additionally, audio output can be provided instead of, or in addition to display output. In another example, if display subsystem 2130 includes a touch screen, the display device also acts as an input device, which can be at least partially managed by I/O controller 2140. There can also be additional buttons or switches on the computing device 2100 to provide I/O functions managed by I/O controller 2140.

In one embodiment, I/O controller 2140 manages devices such as accelerometers, cameras, light sensors or other environmental sensors, or other hardware that can be included in the computing device 2100. The input can be part of direct user interaction, as well as providing environmental input to the system to influence its operations (such as filtering for noise, adjusting displays for brightness detection, applying a flash for a camera, or other features).

In one embodiment, computing device 2100 includes power management 2150 that manages battery power usage, charging of the battery, and features related to power saving operation. Memory subsystem 2160 includes memory devices for storing information in computing device 2100. Memory can include nonvolatile (state does not change if power to the memory device is interrupted) and/or volatile (state is indeterminate if power to the memory device is interrupted) memory devices. Memory subsystem 2160 can store application data, user data, music, photos, documents, or other data, as well as system data (whether long-term or temporary) related to the execution of the applications and functions of the computing device 2100. In one embodiment, computing device 2100 includes a clock generation subsystem 2152 to generate a clock signal.

Elements of embodiments are also provided as a machine-readable medium (e.g., memory 2160) for storing the computer-executable instructions (e.g., instructions to implement any other processes discussed herein). The machine-readable medium (e.g., memory 2160) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 2170 includes hardware devices (e.g., wireless and/or wired connectors and communication hardware) and software components (e.g., drivers, protocol stacks) to enable the computing device 2100 to communicate with external devices. The computing device 2100 could be separate devices, such as other computing devices, wireless access points or base stations, as well as peripherals such as headsets, printers, or other devices.

Connectivity 2170 can include multiple different types of connectivity. To generalize, the computing device 2100 is illustrated with cellular connectivity 2172 and wireless connectivity 2174. Cellular connectivity 2172 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 2174 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 2180 include hardware interfaces and connectors, as well as software components (e.g., drivers, protocol stacks) to make peripheral connections. It will be understood that the computing device 2100 could both be a peripheral device (“to” 2182) to other computing devices, as well as have peripheral devices (“from” 2184) connected to it. The computing device 2100 commonly has a “docking” connector to connect to other computing devices for purposes such as managing (e.g., downloading and/or uploading, changing, synchronizing) content on computing device 2100. Additionally, a docking connector can allow computing device 2100 to connect to certain peripherals that allow the computing device 2100 to control content output, for example, to audiovisual or other systems.

In addition to a proprietary docking connector or other proprietary connection hardware, the computing device 2100 can make peripheral connections 2180 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

In some embodiments, the computing device 2100 may comprise a battery subsystem 2190 comprising a battery 2192 (e.g., which may be a rechargeable battery) and a battery charger 2194. In some embodiments, power generated by the dissimilar photovoltaic layers 2196 may be used to recharge the battery 2192, e.g., by the battery charger 2194. In some embodiments, in addition to the power from the photovoltaic layers 2196, the charger 2194 may also receive power from one or more other power sources to charge the battery 2192, e.g., via a USB link, AC power via an adapter, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following example clauses pertain to further embodiments. Specifics in the example clauses may be used anywhere in one or more embodiments. All optional features of the apparatus described herein may also be implemented with respect to a method or process.

Clause 1. An apparatus comprising: a surface; a first photovoltaic layer formed on a first section of the surface; and a second photovoltaic layer formed on a second section of the surface, wherein a transparency of the first photovoltaic layer is different from a transparency of the second photovoltaic layer.

Clause 2. The apparatus of clause 1, wherein: the first section of the surface is a non-display section of the surface; and the second section of the surface is a display section of the surface.

Clause 3. The apparatus of clause 2, wherein the second photovoltaic layer is more transparent than the first photovoltaic layer.

Clause 4. The apparatus of any of clauses 2-3, wherein: the first photovoltaic layer comprises a first number of layers of photovoltaic material; the second photovoltaic layer comprises a second number of layers of photovoltaic material, the second number being different from the first number.

Clause 5. The apparatus of clause 4, wherein the second number is less than the first number.

Clause 6. The apparatus of any of clauses 1-5, wherein: the first section of the surface is a non-display section of the surface; the second section of the surface is a display section of the surface; the first photovoltaic layer has a first thickness; the second photovoltaic layer has a second thickness; and the second thickness is less than the first thickness.

Clause 7. The apparatus of any of clauses 1-6, further comprising: a third photovoltaic layer formed on a third section of the surface, wherein a transparency of the third photovoltaic layer is different from the transparency of the first photovoltaic layer and the transparency of the second photovoltaic layer.

Clause 8. The apparatus of any of clauses 1-6, wherein the apparatus is a watch, and wherein the apparatus further comprises: a dial comprising a plurality of numbers to indicate time; and third photovoltaic layers formed on the plurality of numbers, wherein a transparency of the third photovoltaic layers is different from the transparency of the first photovoltaic layer and the transparency of the second photovoltaic layer.

Clause 9. The apparatus of any of clause 1-6, wherein the apparatus is a watch, and wherein the apparatus further comprises: an hour hand and a minute hand; and third photovoltaic layers formed on at least one of the hour hand or the minute hand, wherein a transparency of the third photovoltaic layers is different from the transparency of the first photovoltaic layer and the transparency of the second photovoltaic layer.

Clause 10. The apparatus of any of clauses 1-9, further comprising: a battery, wherein the first photovoltaic layer and the second first photovoltaic layer are to receive ambient light and generate power for recharging the battery.

Clause 11. The apparatus of any of clauses 1-10, wherein the apparatus is one of a wearable device or an Internet-of-things (IOT).

Clause 12. A system comprising: a battery; a surface; and a plurality of dissimilar photovoltaic layers formed on the surface, the plurality of dissimilar photovoltaic layers to receive ambient light and generate power to recharge the battery.

Clause 13. The system of clause 12, further comprising: a memory to store instructions; and a processor coupled to the memory, wherein the battery is to at least in part power the memory and the processor.

Clause 14. The system of any of clauses 12-13, wherein the plurality of dissimilar photovoltaic layers comprises: a first photovoltaic layer having a first degree of transparency; and a second photovoltaic layer having a second degree of transparency that is different from the first degree of transparency.

Clause 15. The system of clause 14, wherein: the first photovoltaic layer is formed on a non-display section of the surface; and the second photovoltaic layer is formed on a display section of the surface.

Clause 16. The system of any of clauses 14-15, wherein: the first photovoltaic layer is less transparent than the second photovoltaic layer.

Clause 17. The system of any of clauses 12-16, wherein the system is a wearable device, an Internet-of-things (IOT), a smart watch, smart glasses, and/or a handheld consumer electronic device.

Clause 18. A method comprising: forming a surface, the surface comprising a first section and a second section; forming a first photovoltaic layer on the first section of the surface; and forming a second photovoltaic layer on the second section of the surface,

wherein the first photovoltaic layer is more opaque than the second photovoltaic layer.

Clause 19. The method of clause 18, wherein forming the first photovoltaic layer comprises: masking the second section of the surface using a mask layer, wherein the first section of the surface is exposed through the mask layer; and depositing photovoltaic material on the first section of the surface exposed through the mask layer to form the first photovoltaic layer.

Clause 20. The method of any of clauses 18-19, wherein forming the second photovoltaic layer comprises: masking the first photovoltaic layer using a mask layer, wherein the second section of the surface is exposed through the mask layer; and depositing photovoltaic material on the second section of the surface exposed through the mask layer to form the second photovoltaic layer.

Clause 21. The method of any of clauses 18-20, wherein: the first section of the surface is a non-display section of the surface; and the second section of the surface is a display section of the surface.

Clause 22. The method of any of clauses 18-21, wherein: the first photovoltaic layer comprises a first number of layers of photovoltaic material; and the second photovoltaic layer comprises a second number of layers of photovoltaic material, the second number being different from the first number.

Clause 23. The method of clause 22, wherein: the second number is less than the first number.

Clause 24. One or more non-transitory computer-readable storage media to store instructions that, when executed by a processor, cause the processor to execute a method of any of the clauses 18-23.

Clause 25. An apparatus comprising: means for performing the method of any of the clauses 18-23.

Clause 26. An apparatus comprising: means for forming a surface, the surface comprising a first section and a second section; means for forming a first photovoltaic layer on the first section of the surface; and means for forming a second photovoltaic layer on the second section of the surface, wherein the first photovoltaic layer is more opaque than the second photovoltaic layer.

Clause 27. The apparatus of clause 26, wherein the means for forming the first photovoltaic layer comprises: means for masking the second section of the surface using a mask layer, wherein the first section of the surface is exposed through the mask layer; and means for depositing photovoltaic material on the first section of the surface exposed through the mask layer to form the first photovoltaic layer.

Clause 28. The apparatus of any of clauses 26-27, wherein the means for forming the second photovoltaic layer comprises: means for masking the first photovoltaic layer using a mask layer, wherein the second section of the surface is exposed through the mask layer; and

means for depositing photovoltaic material on the second section of the surface exposed through the mask layer to form the second photovoltaic layer.

Clause 29. The apparatus of any of clauses 26-28, wherein: the first section of the surface is a non-display section of the surface; and the second section of the surface is a display section of the surface.

Clause 30. The apparatus of any of clauses 26-29, wherein: the first photovoltaic layer comprises a first number of layers of photovoltaic material; and the second photovoltaic layer comprises a second number of layers of photovoltaic material, the second number being different from the first number.

Clause 31. The apparatus of clause 30, wherein: the second number is less than the first number.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1. An apparatus comprising:
a surface;
a first photovoltaic layer formed on a first section of the surface; and
a second photovoltaic layer formed on a second section of the surface,
wherein a transparency of the first photovoltaic layer is different from a transparency of the second photovoltaic layer.

2. The apparatus of claim 1, wherein:
the first section of the surface is a non-display section of the surface; and
the second section of the surface is a display section of the surface.

3. The apparatus of claim 2, wherein the second photovoltaic layer is more transparent than the first photovoltaic layer.

4. The apparatus of claim 2, wherein:
the first photovoltaic layer comprises a first number of layers of photovoltaic material;
the second photovoltaic layer comprises a second number of layers of photovoltaic material, the second number being different from the first number.

5. The apparatus of claim 4, wherein the second number is less than the first number.

6. The apparatus of claim 1, wherein:
the first section of the surface is a non-display section of the surface;
the second section of the surface is a display section of the surface;
the first photovoltaic layer has a first thickness;
the second photovoltaic layer has a second thickness; and
the second thickness is less than the first thickness.

7. The apparatus of claim 1, further comprising:
a third photovoltaic layer formed on a third section of the surface,
wherein a transparency of the third photovoltaic layer is different from the transparency of the first photovoltaic layer and the transparency of the second photovoltaic layer.

8. The apparatus of claim 1, wherein the apparatus is a watch, and wherein the apparatus further comprises:
a dial comprising a plurality of numbers to indicate time; and
third photovoltaic layers formed on the plurality of numbers,
wherein a transparency of the third photovoltaic layers is different from the transparency of the first photovoltaic layer and the transparency of the second photovoltaic layer.

9. The apparatus of claim 1, wherein the apparatus is a watch, and wherein the apparatus further comprises:
an hour hand and a minute hand; and
third photovoltaic layers formed on at least one of the hour hand or the minute hand,
wherein a transparency of the third photovoltaic layers is different from the transparency of the first photovoltaic layer and the transparency of the second photovoltaic layer.

10. The apparatus of claim 1, further comprising:
a battery,
wherein the first photovoltaic layer and the second first photovoltaic layer are to receive ambient light and generate power for recharging the battery.

11. The apparatus of claim 1, wherein the apparatus is one of a wearable device or an Internet-of-things (IOT).

12. A system comprising:
a battery;
a surface; and
a plurality of dissimilar photovoltaic layers formed on the surface, the plurality of dissimilar photovoltaic layers to receive ambient light and generate power to recharge the battery.

13. The system of claim 12, further comprising:
a memory to store instructions; and
a processor coupled to the memory,
wherein the battery is to at least in part power the memory and the processor.

14. The system of claim 12, wherein the plurality of dissimilar photovoltaic layers comprises:
a first photovoltaic layer having a first degree of transparency; and
a second photovoltaic layer having a second degree of transparency that is different from the first degree of transparency.

15. The system of claim 14, wherein:
the first photovoltaic layer is formed on a non-display section of the surface; and
the second photovoltaic layer is formed on a display section of the surface.

16. The system of claim 15, wherein:
the first photovoltaic layer is less transparent than the second photovoltaic layer.

17. The system of claim 12, wherein the system is a wearable device, an Internet-of-things (IOT), a smart watch, smart glasses, and/or a handheld consumer electronic device.

18. A method comprising:
forming a surface, the surface comprising a first section and a second section;
forming a first photovoltaic layer on the first section of the surface; and
forming a second photovoltaic layer on the second section of the surface,
wherein the first photovoltaic layer is more opaque than the second photovoltaic layer.

19. The method of claim 18, wherein forming the first photovoltaic layer comprises:
masking the second section of the surface using a mask layer, wherein the first section of the surface is exposed through the mask layer; and
depositing photovoltaic material on the first section of the surface exposed through the mask layer to form the first photovoltaic layer.

20. The method of claim 18, wherein forming the second photovoltaic layer comprises:
masking the first photovoltaic layer using a mask layer, wherein the second section of the surface is exposed through the mask layer; and
depositing photovoltaic material on the second section of the surface exposed through the mask layer to form the second photovoltaic layer.
